(19) United States
(12) Patent Application Publication
(10) Pub. No.: US 2011/0248360 A1
(43) Pub. Date: Oct. 13, 2011

(54) HIGH-SPEED TRANSISTOR STRUCTURE AND METHOD FOR MANUFACTURING THE SAME

(75) Inventors: Zhijiong Luo, Poughkeepsie, NY (US); Huilong Zhu, Poughkeepsie, NY (US); Haizhou Yin, Poughkeepsie, NY (US)

(73) Assignee: INSTITUTE OF MICROELECTRONICS, CHINESE ACADEMY OF SCIENCES, Beijing (CN)

(21) Appl. No.: 13/063,727

(22) PCT Filed: Sep. 26, 2010
(86) PCT No.: PCT/CN10/77295

§ 371 Date: Mar. 11, 2011

(30) Foreign Application Priority Data
Apr. 7, 2010 (CN) 201010142039.9

(51) Int. Cl. H01L 29/78; H01L 21/28

(52) U.S. Cl. 257/411; 438/591; 257/E29.255; 257/E21.19

(57) ABSTRACT

The present invention relates to a high-speed transistor device and a method for fabricating the same. A high-speed transistor device is proposed, comprising: a silicon substrate; and a gate stack formed on the silicon substrate. The gate stack comprises a gate dielectric stack and a gate electrode layer, and the gate dielectric stack comprises at least a SrTiO₃ layer and a LaAlO₃ layer positioned thereon. The electron concentration is improved by the two-dimensional electron gas generated ascribing to a triangular potential well formed between the SrTiO₃ layer and the LaAlO₃ layer. Meanwhile, since the channel is formed between the SrTiO₃ layer and the LaAlO₃ layer, the electrons and the scattering center are seperated from each other, such that the electron mobility is enhanced, which accordingly improves the speed of the transistor device.

### FIELD OF THE INVENTION

The present invention generally relates to a high-speed transistor device and a method for manufacturing the same, and more specifically, to such a transistor device and a method for manufacturing the same that the speed of the transistor is increased by forming a special gate dielectric stack so as to improve the electron concentration within the gate stack, thereby enhancing the electron mobility.

### BACKGROUND OF THE INVENTION

With the development of the semiconductor industry, integrated circuits with higher performance and more powerful functions require greater element density. Thus, the size of the components need to be scaled further. Accordingly, in order to improve the performance of the Metal Oxide Semiconductor Field Effect Transistor (MOSFET), the electron mobility in the gate should be further enhanced

Therefore, in order to improve the performance of transistor devices, a high-speed transistor structure and a method for manufacturing the same are needed to enhance the electron mobility within the gate so as to increase the speed of the transistor device.

### SUMMARY OF THE INVENTION

In order to solve the above-mentioned problems, the present invention proposes a high-speed transistor device, which comprises: a silicon substrate; and a gate stack formed on the silicon substrate, wherein the gate stack comprises a gate dielectric stack and a gate electrode layer, and the gate dielectric stack comprises at least a SrTiO₃ layer and a LaAlO₃ layer positioned thereon. The SrTiO₃ layer has a thickness smaller than 20 Å, and the LaAlO₃ layer has a thickness greater than that of the SrTiO₃ layer.

Besides, the present invention further provides methods for fabricating a high-speed transistor device by means of the gate-first process and the gate-last process, respectively. The method for fabricating a high-speed transistor device by means of the gate-last process comprises: a) providing a substrate; b) forming a dummy gate stack and sidewall spacers on the substrate, a source region and a drain region in the substrates at the both sides of the dummy gate stack, and an interlayer dielectric layer covering the device; c) removing the dummy gate stack so as to form an opening; d) epitaxially growing a SrTiO₃ layer within the opening; e) epitaxially growing a LaAlO₃ layer on the SrTiO₃ layer; and f) depositing a gate electrode layer on the LaAlO₃ layer. The method for fabricating a high-speed transistor device by means of the gate-first process comprises: a) providing a substrate; b) epitaxially growing a SrTiO₃ layer on the substrate; c) epitaxially growing a LaAlO₃ layer on the SrTiO₃ layer; and d) depositing a gate electrode layer on the LaAlO₃ layer.

The electron concentration is improved by the two-dimensional electron gas produced ascribing to a triangular potential well formed between the SrTiO₃ layer and the LaAlO₃ layer. Meanwhile, since the channel is formed between the SrTiO₃ layer and the LaAlO₃ layer, the electrons and the scattering center are separated from each other, such that the electron mobility is enhanced, which accordingly improves the speed of the transistor device.

### BRIEF DESCRIPTION OF THE DRAWINGS

FIG. 1 illustrates the structure of the transistor device according to the first embodiment of the present invention.

FIG. 2 is a flowchart illustrating the method of fabricating the transistor device according to the first embodiment of the present invention.

FIGS. 3 and 4 show the structures of the transistor device at different fabrication steps according to the first embodiment of the present invention.

FIG. 5 illustrates the structure of the transistor device according to a second embodiment of the present invention.

FIG. 6 is a flowchart illustrating the method of fabricating the transistor device according to the second embodiment of the present invention.

FIG. 7 illustrates a diagram for the energy band of the high-speed transistor device.

### DETAILED DESCRIPTION OF THE INVENTION

The present invention generally relates to a high-speed transistor structure and a method for fabricating the same, and particularly, to such a transistor device and a method for fabricating the same that the speed of the transistor is increased by forming a special gate dielectric stack so as to improve the electron concentration within the gate stack, thereby enhancing the electron mobility.

The following disclosure provides a plurality of different embodiments or examples to achieve different structures of the present invention. To simplify the disclosure of the present invention, description of the components and arrangements of specific examples is given. Of course, they are only illustrative and not limiting the present invention. Moreover, in the present invention, reference number(s) and/or letter(s) may be repeated in different embodiments. Such repetition is for the purposes of simplification and clearness, and does not denote the relationship between the respective embodiments and/or arrangements being discussed. In addition, the present invention provides various examples for specific processes and materials. However, it is obvious for a person of ordinary skill in the art that other process and/or materials may alternatively be utilized. Furthermore, the following structure in which a first object is “on” a second object may include an embodiment in which the first object and the second object are formed to be in direct contact with each other, and may also include an embodiment in which another object is formed between the first object and the second object such that the first and second objects might not be in direct contact with each other.

### First Embodiment

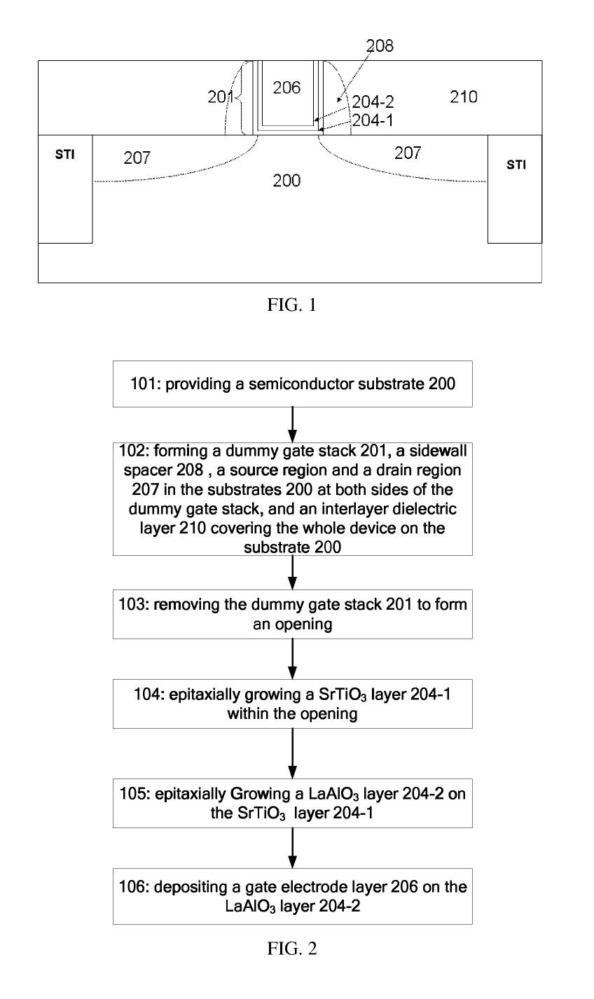

FIG. 1, with reference thereto, illustrates the structure of the transistor device according to the first embodiment of the present invention. As shown in FIG. 1, the transistor device of the present invention is fabricated by the gate-last process (replacement gate process). The transistor device fabricated according to such a method comprises: a silicon substrate 200; a source region and a drain region 207 formed in the substrate; and a gate stack 201 and its sidewall spacer 208 formed on the silicon substrate. The gate stack comprises a gate dielectric stack 204 and a gate electrode layer 206. The gate dielectric stack 204 comprises a SrTiO₃ layer 204-1 and a LaALO₃ layer 204-2 positioned thereon, and the gate dielectric stack 204 covers the substrate and the side surfaces of the sidewall spacer 208. Optionally, the device further comprises an interlayer dielectric layer 210 that covers the transistor device. The SrTiO₃ layer 204-1 has a thickness smaller than 20 Å, and the the LaAlO₃ layer 204-2 has a thickness greater than that of the SrTiO₃ layer.

FIG. 7 illustrates the diagram for the energy band of the high-speed transistor device shown in FIG. 1. According to the energy band theory, the energy bands of the SrTiO₃ layer 204-1, the LaAlO₃ layer 204-2 and the silicon substrate of the high-speed transistor are slanted due to the Fermi level difference of the respective layers and the applied gate voltage. As can be seen from FIG. 7, triangular potential wells of electrons are formed both between the SrTiO₃ layer 204-1 and the LaAlO₃ layer 204-2, and between the SrTiO₃ layer 204-1 and the silicon substrate 200, such that the movement of electrons along the direction vertical to the substrate 200 is constrained and a two-dimensional electron gas is generated. In the area near the source region, the two-dimensional electron gas on the surface of the silicon substrate tunnels into the potential well between the SrTiO₃ layer 204-1 and the LaAlO₃ layer 204-2 by the application of the gate voltage, which may thus increase the electron concentration between the SrTiO₃ layer 204-1 and the LaAlO₃ layer 204-2; and in the area near the drain region, the electrons between the SrTiO₃ layer 204-1 and the LaAlO₃ layer 204-2 tunnels into the potential well at the surface of the substrate by the application of the drain and gate voltages, which thus achieves the current flow from the drain to the source.

Accordingly, the electron concentration is improved on account of the two-dimensional electron gas generated ascribing to the triangular well formed between the SrTiO₃ layer 204-1 and the LaAlO₃ layer 204-2. Meanwhile, since the channel is formed between the SrTiO₃ layer 204-1 and the LaAlO₃ layer 204-2, the electrons and the scattering center are separated from each other, and thence the electron mobility is enhanced, which accordingly increases the speed of the transistor device.

With reference to FIG. 2, the flowchart of the method for fabricating the transistor device according to the first embodiment of the present invention is described hereafter.

In step 101, a semiconductor substrate 200 is provided, wherein the substrate 200 includes a crystalline silicon substrate (for example, a wafer). The substrate 200 is preferably a p-type substrate, and may be of various doping configurations. Other examples of the substrate 200 may also include other basic semiconductors, for example, germanium and diamond. Alternatively, the substrate 200 may include compound semiconductors, such as SiC, GaAs, InAs or InP. Additionally, the substrate 200 may include an epitaxial layer, may be under stress to enhance performance, and/or may include a SOI (silicon on insulator) structure.

In step 102, a dummy gate stack 201 and a sidewall spacer 208 are formed on the substrates, source/drain regions 207 are formed in the substrate at both sides of the dummy gate stack 201, and an interlayer dielectric layer 210 is formed to cover the device. The dummy gate stack 201 comprises a dummy gate dielectric layer and a dummy gate. The dummy gate dielectric layer may be a thermal oxide layer including silicon oxide, silicon nitride, for example, silicon dioxide. The dummy gate is a sacrificial layer, and may be, for example, polysilicon. In one embodiment, the dummy gate may include amorphous silicon. The dummy gate stack 201 may be formed by a conventional Metal Oxide Semiconductor (MOS) process, such as deposition, lithography, etching and/or other appropriate methods.

The source/drain regions 207 may be formed by implanting, depending on the desired transistor structure, p-type or n-type dopants into the substrate 200. The source/drain regions 207 may be formed by a method including lithography, ion implantation, diffusion and/or other process as appropriate. The device is then annealed by conventional semiconductor process, so as to activate the dopants within the source and drain regions 207; and the thermal annealing may be carried out by using rapid thermal annealing, spike annealing, and other processes that are known to a person skilled in the art.

A sidewall spacer 208 may be formed to cover the dummy gate stack 201. The sidewall spacer 208 may be formed of silicon nitride, silicon dioxide, siliconoxynitride, silicon carbide, fluorine-doped silicate glass, low-k dielectric materials, and/or other materials as appropriate and any combination thereof. The sidewall spacer 208 may have a multilayer structure, and may be formed by appropriate methods including depositing appropriate dielectric materials. Such a structure may be fabricated following the process that is known to a person skilled in the art.

Particularly, an interlayer dielectric layer (ILD) 210 may be deposited on the substrate, which may be, but not limited to, undoped silicon oxide (SiO₂), doped silicon oxide (for example, borosilicate glass, borophosphosilicate glass, etc.) and silicon nitride (Si₃N₄). The interlayer dielectric layer 210 may be formed by using a method such as Chemical Vapor Deposition (CVD), Physical Vapor Deposition (PVD), Atom Layer Deposition (ALD) and/or other process as appropriate. The interlayer dielectric layer 210 may have a multilayer structure. In one embodiment, the interlayer dielectric layer 210 may have a thickness in the range from about 30 to 90 nm.

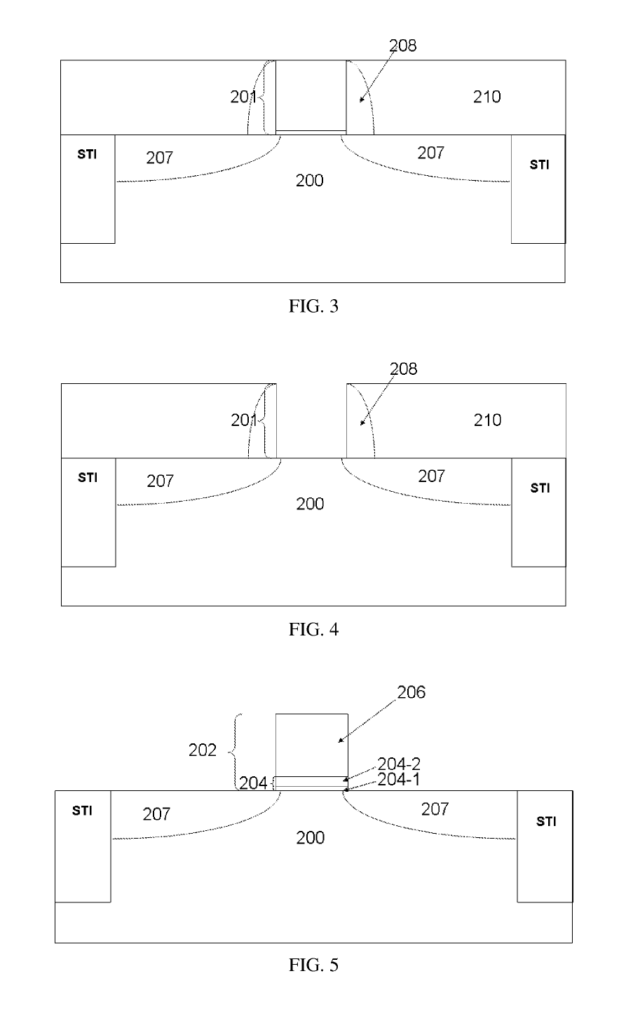

Then a planarization process is applied to both the interlayer dielectric layer 210 and the sidewall spacer 208 so as to expose the upper surface of the dummy gate. For example, the interlayer dielectric layer 210 may be removed by Chemical Mechanical Polishing (CMP) process to expose the upper surface of the sidewall spacer 208. Then, CMP or Reaction Ion Etching (RIE) is applied to the sidewall spacer 208 so as to remove its upper surface, such that the dummy gate is exposed as shown in FIG. 3.

Then the flow goes to step 103 in which the dummy gate stack 201 is removed so as to form an opening, as shown in FIG. 4. For example, by selectively etching polysilicon and the dummy gate dielectric layer, the dummy gate and the dummy gate dielectric layer are removed and the opening is formed. The dummy gate and the dummy gate dielectric layer may be removed by using wet etching and/or dry etching. In one embodiment, Tetramethylammonium hydroxide (TMAH), Potassium hydroxide (KOH) or other etchant solution(s) as appropriate may be utilized in the wet etching process.

In step 104, a SrTiO₃ layer 204-1 having a thickness smaller than 20 Å is epitaxially grown within the opening Then in step 105, a LaAlO₃ layer 204-2 having a thickness greater than that of the SrTiO₃ layer 204-1 is epitaxially grown on the SrTiO₃ layer 204-1. In such a process, the SrTiO₃ layer 204-1 and the LaAlO₃ layer 204-2 cover both the substrate under the opening and the side surface(s) of the sidewall spacers.

In step 106, a gate electrode layer 206 is deposited on the LaAlO₃ layer 204-2, as shown in FIG. 1. The metal gate may include one or more material layers, for example, one or more liners, so as to provide the gate with materials having suitable work functions, gate electrode materials, and/or other materials as appropriate. For an N-type semiconductor device, one or more materials may be deposited selected from the following group comprising TiN, TiAlN, TaAlN, TaN, TaSiN, HfSiN, MoSiN, RuTaₓ, NiTaₓ and any combination thereof. For a P-type semiconductor device, one or more materials may be deposited selected from the following group comprising TiN, TiSiN, TiCN, TaAlC, TiAlN, TaN, PtSiₓ, Ni₃Si, Pt, Ru, Ir, Mo, HfRu, RuOₓ and any combination thereof.

Afterwards, other following processes, such as CMP or the like, are applied to the device according to requirements in device design.

### Second Embodiment

The description below will focus on the aspects in which the second embodiment differs from the first embodiment. The part(s) not described here should be construed as being carried out with the same steps, methods or processes as those applied in the first embodiment, and thus is/are omitted here for brevity. In the second embodiment of the present invention, as shown in FIG. 5, the transistor device is fabricated by gate-first process, and comprises a silicon substrate 200, and a gate stack 202 formed on the silicon substrate. The gate stack 202 comprises a gate dielectric stack 204 and a gate electrode layer 206, and the gate dielectric stack 204 comprises a SrTiO₃ layer 204-1 and a LaAlO₃ layer 204-2 positioned thereon. Additionally, the high-speed transistor device further comprises source/drain regions 207 which are formed in the substrates at both sides of the gate stack. The SrTiO₃ layer 204-1 has a thickness smaller than 20 Å, and the LaAlO₃ layer 204-2 has a thickness greater than that of the SrTiO₃ layer, as shown in FIG. 5.

FIG. 7 illustrates the diagram for the energy band of the high-speed transistor device shown in FIG. 5. According to the energy band theory, the energy bands of the SrTiO₃ layer 204-1, the LaAlO₃ layer 204-2 and the silicon substrate of the high-speed transistor are slanted due to the Fermi level difference of the respective layers and the applied gate voltage. As can be seen from the figure, triangular potential wells of electrons are formed both between the SrTiO₃ layer 204-1 and the LaAlO₃ layer 204-2, and between the SrTiO₃ layer 204-1 and the silicon substrate 200, such that the movement of electrons along the direction vertical to the substrate 200 is constrained and a two-dimensional electron gas is generated. In the area near the source region, the two-dimensional electron gas on the surface of the silicon substrate tunnels into the potential well between the SrTiO₃ layer 204-1 and the LaAlO₃ layer 204-2 under the application of the gate voltage, which may thus increase the electron concentration between the SrTiO₃ layer 204-1 and the LaAlO₃ layer 204-2; and in the area near the drain region, the electrons between the SrTiO₃ layer 204-1 and the LaAlO₃ layer 204-2 tunnels into the potential well at the surface of the substrate under the application of the drain and gate voltages, which thus achieves the current flow from the drain to the source.

Accordingly, the electron concentration is improved on account of the two-dimensional electron gas generated ascribing to the triangular potential well formed between the SrTiO₃ layer 204-1 and the LaAlO₃ layer 204-2. Meanwhile, since the channel is formed between the SrTiO₃ layer and the LaAlO₃ layer, the electrons and the scattering center are separated from each other, and thence the electron mobility is enhanced, which accordingly increases the speed of the transistor device.

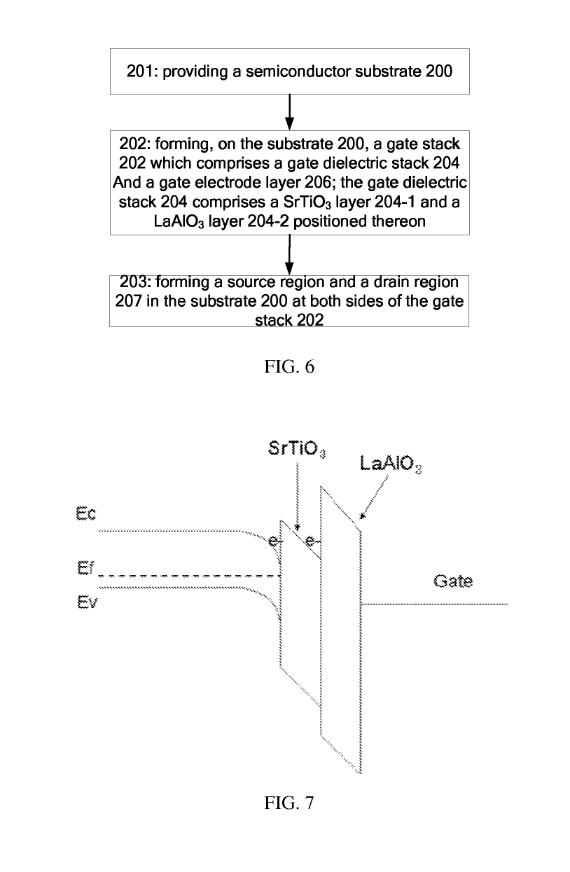

With reference to FIG. 6, the flowchart of the method for fabricating the transistor device according to the second embodiment of the present invention is depicted hereafter.

In step 201, a semiconductor substrate 200 is provided, wherein the substrate 200 includes a crystalline silicon substrate (for example, a wafer). The substrate 200 is preferably a p-type substrate, and may be of various doping configurations. Other examples of the substrate 200 may also include other basic semiconductors, for example germanium and diamond. Alternatively, the substrate 200 may include compound semiconductors, such as SiC, GaAs, InAs or InP. Additionally, the substrate 200 may optionally include an epitaxial layer, may be under stress to enhance performance, and/or may include a SOI (silicon on insulator) structure.

In step 202, a gate stack 202 is formed on the substrate 200. The gate stack 202 comprises a gate dielectric stack 204 and a gate electrode layer 206. The gate dielectric stack 204 comprises a SrTiO₃ layer 204-1 and a LaAlO₃ layer 204-2 positioned thereon. The SrTiO₃ layer 204-1 may have a thickness smaller than 20 Å, and the LaAlO₃ layer 204-2 may have a thickness greater than that of the SrTiO₃ layer 204-1. The SrTiO₃ layer 204-1 and the LaAlO₃ layer 204-2 are formed by epitaxial growth.

In step 203, source/drain regions 207 are formed in the substrate 200 at both sides of the gate stack 202. Then, other following processes, such as CMP or the like, are performed to the transistor device according to the requirements in the device design.

The principle of the present invention has been described in detail according to the first and the second embodiments of the present invention, wherein the electron concentration is improved on account of the two-dimensional electron gas generated ascribing to the triangular potential well formed between the SrTiO₃ layer 204-1 and the LaAlO₃ layer 204-2. Meanwhile, since the channel is formed between the SrTiO₃ layer 204-1 and the LaAlO₃ layer 204-2, the electrons and the scattering center are separated from each other, and thence the electron mobility is enhanced, which accordingly improves the speed of the transistor device.

Although the embodiments and their advantages have been described in detail, it is readily apparent to those having ordinary skill in the art that various alterations, substitutions and modifications may be made to the embodiments without departing from the spirit of the present invention and the scope as defined by the appended claims. For other examples, it may be easily recognized by a person of ordinary skill in the art that the order of the process steps may be changed without departing from the scope of the present invention.

In addition, the scope to which the present invention is applied is not limited to the process, mechanism, manufacture, material composition, means, methods and steps described in the specific embodiments in the specification. A person of ordinary skill in the art would readily appreciate from the disclosure of the present invention that the process, mechanism, manufacture, material composition, means, methods and steps currently existing or to be developed in future, which perform substantially the same functions or achieve substantially the same as that in the corresponding embodiments described in the present invention, may be applied according to the present invention. Therefore, it is intended that the scope of the appended claims of the present invention includes these process, mechanism, manufacture, material composition, means, methods or steps.

What is claimed is:

1. A high-speed transistor device, comprising:
a silicon substrate;
a gate stack formed on the silicon substrate,
wherein the gate stack comprises a gate dielectric stack and a gate electrode layer; and
the gate dielectric stack comprises at least a SrTiO₃ layer and a LaAlO₃ layer positioned thereon.

2. The high-speed transistor device according to claim 1, further comprising a source region and a drain region formed in the substrate at both sides of the gate stack.

3. The high-speed transistor device according to claim 1, wherein the SrTiO₃ layer has a thickness smaller than 20 Å.

4. The high-speed transistor device according to claim 1, wherein the LaAlO₃ layer has a thickness greater than that of the SrTiO₃ layer.

5. A method for fabricating a high-speed transistor device, comprising:
a) providing a substrate;
b) epitaxially growing a SrTiO₃ layer on the substrate;
c) epitaxially growing a LaAlO₃ layer on the SrTiO₃ layer; and
d) depositing a gate electrode layer on the LaAlO₃ layer.

6. A method for fabricating a high-speed transistor device, comprising:
a) providing a substrate;
b) forming a dummy gate stack, a sidewall spacer, a source region and a drain region in the substrates at both sides of the dummy gate stack, and an interlayer dielectric layer covering the device on the substrate;
c) removing the dummy gate stack to form an opening;
d) epitaxially growing a SrTiO₃ layer within the opening;
e) epitaxially growing a LaAlO₃ layer on the SrTiO₃ layer; and
f) depositing a gate electrode layer on the LaAlO₃ layer.

7. The method according to any one of claims 5 and 6, wherein the SrTiO₃ layer has a thickness smaller than 20 Å.

8. The method according to any one of claims 5 and 6, wherein the LaAlO₃ layer has a thickness greater than that of the SrTiO₃ layer.
